(19) United States
(12) Patent Application Publication
(10) Pub. No.: US 2025/0220906 A1
(43) Pub. Date: Jul. 3, 2025

(54) MEMORY DEVICE AND ELECTRONIC APPARATUS INCLUDING THE SAME

(71) Applicant: SAMSUNGE ELECTRONICS CO., LTD., Suwon-si (KR)

(72) Inventors: Hyunjae SONG, Suwon-si (KR); Yumin KIM, Suwon-si (KR); Garam PARK, Suwon-si (KR); Seungdam HYUN, Suwon-si (KR)

(73) Assignee: SAMSUNGE ELECTRONICS CO., LTD., Suwon-si (KR)

(21) Appl. No.: 19/009,262

(22) Filed: Jan. 3, 2025

(30) Foreign Application Priority Data
Jan. 3, 2024 (KR) 10-2024-0000902
Mar. 11, 2024 (KR) 10-2024-0034097

(51) Int. Cl. H10B 43/27; H10N 70/00

(52) U.S. Cl. CPC H10B 43/27; H10N 70/8833

(57) ABSTRACT

Provided is a memory device including a channel layer, a first dielectric constant change layer on the channel layer, a second dielectric constant change layer spaced apart from the first dielectric constant change layer, and a diffusion barrier layer between the first dielectric constant change layer and the second dielectric constant change layer, wherein the first dielectric constant change layer and the second dielectric constant change layer include oxygen vacancies.

### CROSS-REFERENCE TO RELATED APPLICATIONS

This application claims priority to Korean Patent Application Nos. 10-2024-0000902, filed on Jan. 3, 2024, and 10-2024-0034097, filed on Mar. 11, 2024, in the Korean Intellectual Property Office, the disclosures of which are incorporated by reference herein in their entireties.

### BACKGROUND

### 1. Field

Embodiments of the present disclosure relate to a memory device and

an electronic apparatus including the same.

### 2. Description of Related Art

A nonvolatile memory device as a semiconductor memory device does not lose stored data even when the supply of power is interrupted, and may be, for example, a programmable read-only memory (ROM) (PROM), an erasable programmable PROM (EPROM), an electrically EPROM (EEPROM), a flash memory device, and the like.

Recently, a vertical NAND (VNAND) device requiring high integration and low power has been studied as a nonvolatile memory device. As the degree of integration increases, in order to overcome the limitations of existing VNAND devices that store information using charge trap layers, new materials such as resistance change materials are being developed and VNAND devices with new structures are being studied.

### SUMMARY

One or more example embodiments provide a memory device with improved operation characteristics and an electronic apparatus including the same.

Additional aspects will be set forth in part in the description which follows and, in part, will be apparent from the description, or may be learned by practice of example embodiments.

According to an aspect of an example embodiment, there is provided a memory device including a channel layer, a first dielectric constant change layer on the channel layer, a second dielectric constant change layer spaced apart from the first dielectric constant change layer, and a diffusion barrier layer between the first dielectric constant change layer and the second dielectric constant change layer, wherein the first dielectric constant change layer and the second dielectric constant change layer include oxygen vacancies.

The first dielectric constant change layer may include at least one of HfOₓ, TaOₓ, WOₓ, GdOₓ, InOₓ, MoOₓ, TiOₓ, VOₓ, ZnO, AlOₓ, and InGaZnOₓ.

The second dielectric constant change layer may include at least one of HfOₓ, TaOₓ, WOₓ, GdOₓ, InOₓ, MoOₓ, TiOₓ, VOₓ, ZnO, AlOₓ, and InGaZnOₓ.

The diffusion barrier layer may be configured to selectively diffuse oxygen ions.

The diffusion barrier layer may include at least one of Al₂O₃, HfO₂, SmNiOₓ, WO₃, yttrium stabilized zirconium oxide (YSZ) and VO2.

The channel layer may include silicon or oxide semiconductor.

The oxide semiconductor may include at least one of ITO, FTO, and InGaZnOₓ.

A thickness of the first dielectric constant change layer may range from 1 nm to 10 nm.

A thickness of the second dielectric constant change layer may range from 1 nm to 10 nm.

According to another aspect of an example embodiment, there is provided a memory device including a plurality of memory cell arrays extending in a first direction normal to a first surface of a substrate, wherein each memory cell array of the plurality of memory cell arrays includes a channel layer extending in the first direction, a plurality of gate electrodes spaced apart from each other in a second direction different from the first direction, and alternately disposed in the first direction, a first dielectric constant change layer in the channel layer, a second dielectric constant change layer spaced apart from the first dielectric constant change layer in the second direction, and a diffusion barrier layer between the first dielectric constant change layer and the second dielectric constant change layer, wherein the first dielectric constant change layer and the second dielectric constant change layer include oxygen vacancies.

The first dielectric constant change layer may include at least one of HfOₓ, TaOₓ, WOₓ, GdOₓ, InOₓ, MoOₓ, TiOₓ, VOₓ, ZnO, and InGaZnOₓ.

The second dielectric constant change layer may include at least one of HfOₓ, TaOₓ, WOₓ, GdOₓ, InOₓ, MoOₓ, TiOₓ, VOₓ, ZnO, and InGaZnOₓ.

The diffusion barrier layer may be configured to selectively diffuse oxygen ions.

The diffusion barrier layer may include at least one of Al₂O₃, HfO₂, SmNiOₓ, WO₃, and VO₂.

The channel layer may include silicon or oxide semiconductor.

The oxide semiconductor may include at least one of ITO, FTO, and InGaZnOₓ.

The memory device may further include a channel hole extending in the first direction and inside the channel layer.

The channel layer, the first dielectric constant change layer, the second dielectric constant change layer, and the diffusion barrier layer may have a cylindrical shape in the channel hole.

The memory device may further include a gate insulating layer between the plurality of gate electrodes and the second dielectric constant change layer.

According to still another aspect of an example embodiment, there is provided an electronic apparatus including a memory device including a channel layer, a first dielectric constant change layer on the channel layer, a second dielectric constant change layer spaced apart from the first dielectric constant change layer, and a diffusion barrier layer between the first dielectric constant change layer and the second dielectric constant change layer, wherein the first dielectric constant change layer and the second dielectric constant change layer includes oxygen vacancies.

### BRIEF DESCRIPTION OF THE DRAWINGS

The above and other aspects, features, and advantages of example embodiments will be more apparent from the following description taken in conjunction with the accompanying drawings, in which:

FIG. 1 is a cross-sectional view illustrating a structure of a memory device according to an example embodiment;

FIG. 2 is an enlarged view of part A of the memory device shown in FIG. 1;

FIGS. 3, 4, and 5 are diagrams illustrating operation methods of memory cells;

FIG. 6 is a cross-sectional view illustrating a structure of a memory device according to an example embodiment;

FIG. 7 is a block diagram illustrating an electronic apparatus including a memory device according to an example embodiment;

FIG. 8 is a block diagram illustrating a memory system including a memory device according to an example embodiment; and

FIG. 9 is a diagram illustrating a neuromorphic device including a memory device according to an example embodiment.

### DETAILED DESCRIPTION

Reference will now be made in detail to embodiments, examples of which are illustrated in the accompanying drawings, wherein like reference numerals refer to like elements throughout. In this regard, example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a memory device and an electronic apparatus including the same will be described in detail with reference to the accompanying drawings. In the following drawings, the same or similar reference numerals refer to the same or similar components, and the size of each component in the drawings may be exaggerated for clarity and convenience of description. In addition, embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “includes” a component, this means that it may further include other components, rather than excluding other components, unless otherwise stated.

The use of the term “the” and similar indicative terms may correspond to both singular and plural. Unless there is clear order or contrary description of the steps constituting the method, these steps may be performed in the appropriate order, and are not necessarily limited to the order described.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

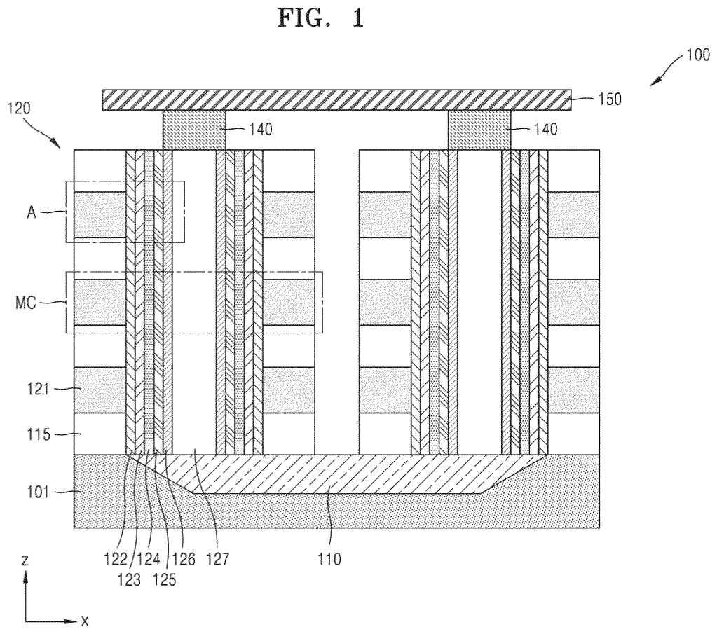

FIG. 1 is a cross-sectional view illustrating a structure of a memory device according to an example embodiment.

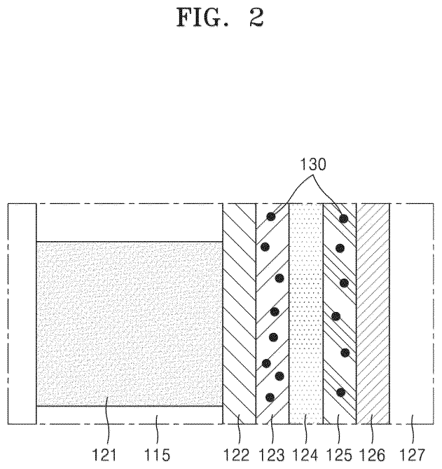

FIG. 2 is an enlarged view of part A of the memory device shown in FIG. 1.

Referring to FIGS. 1 and 2, a memory device 100 may include a substrate 101 and a plurality of memory cell arrays 120 provided on an upper surface of the substrate 101.

Each of the memory cell arrays 120 includes a plurality of memory cells MC arranged in one direction. Each of the memory cells MC includes channel layers 126 extending in a first direction (z-axis direction), a plurality of gate electrodes 121 spaced apart from each other in a second direction (x-axis direction) different from the first direction and alternately arranged in the first direction, gate insulating layers 122 provided corresponding to the gate electrodes 121, respectively, a first dielectric constant change layer 125 provided in each of the channel layers 126, a second dielectric constant change layer 123 arranged to be spaced apart from the first dielectric constant change layer 125 in the second direction, a diffusion barrier layer 124 provided between the first dielectric constant change layer 125 and the second dielectric constant change layer 123, and a filling insulating layer 127. Each of the gate insulating layers 122, the first dielectric constant change layers 125, the diffusion barrier layers 124, the second dielectric constant change layers 123, and the channel layers 126 is provided to extend in a direction perpendicular to the substrate 101, and may be shared by the plurality of memory cells MC. For example, the channel layers 126 may extend in a direction normal to the upper surface of the substrate 101.

The memory device 100 may also include a common source region 210 provided on the substrate 101 and in which the plurality of memory cell arrays 120 are arranged, a drain 140 provided on each of the memory cell arrays 120, and a bit line 150 provided on the drains 140.

Each of the memory cell arrays 120 may be provided to extend in a direction (Z direction) perpendicular to the substrate 101. The plurality of memory cell arrays 120 may be arranged on the substrate 101 in various forms. The memory cell array 120 may have a cylindrical shape, but is not limited thereto. For example, the memory cell array 120 may have a square column shape. Two memory cell arrays 120 are illustrated in the drawing, but this is an example, and the number of memory cells MC included in the memory cell array 120 are not limited thereto. The plurality of memory cell arrays 120 each including an arbitrary number of memory cells MC may be two-dimensionally arranged along the X and Y directions.

The substrate 101 may include various materials. For example, the substrate 101 may include a single crystal silicon substrate, a compound semiconductor substrate, or a silicon on insulator (SOI) substrate, but is not limited thereto. In addition, the substrate 101 may further include impurity areas by doping, electronic devices such as transistors, or peripheral circuits that select and control memory cells that store data.

Interlayer insulating layers 115 and gate electrodes 121 may be alternately stacked on the substrate 101 in a direction perpendicular to the substrate 101. Each interlayer insulating layer 115 and each gate electrode 121 may be provided in parallel to the substrate 101.

The substrate 101 may include a silicon material doped with first type impurities. The substrate 101 may include, for example, a silicon material doped with p-type impurities. The substrate 101 may be, for example, a p-type well. However, the substrate 101 is not limited to p-type silicon.

The common source region 110 may be provided on the substrate 101. The common source region 110 may have a second type impurity different from the first type impurities of the substrate 101. The common source region 110 may have, for example, an n-type. However, the common source region 110 is not limited to an n-type.

The drain 140 may be provided on the memory cell array 120. The drain 140 may include, for example, a silicon material doped with a second type impurity. For example, the drain 140 may include a silicon material doped with an n-type. The drain 140 may be provided on the channel layer 126 and connected to the channel layer 126.

The bit line 150 may be provided on the drain 140. The drain 140 and the bit line 150 may be connected through a contact plug. The channel layers 126 may be connected to the bit line 150 through the drain 140.

The plurality of gate electrodes 121 control the corresponding channel layers 126, and a word line may be electrically connected to the gate electrodes 121. The gate electrode 121 may include, for example, a metal material having relatively high electrical conductivity, such as, for example, gold (Au), titanium (Ti), or tungsten (W), metal nitride, impurity-doped silicon, or a two-dimensional conductive material. However, embodiments are not limited thereto, and the gate electrode 121 may include various other materials.

The plurality of gate electrodes 121 are spaced apart from each other in the first direction (Z direction). The number of illustrated gate electrodes 121 is an example and is not limited to the illustrated number. The number of the gate electrodes 121 corresponds to the number of the memory cells MC individually controlled by the memory device 100, and the corresponding memory cells MC may be controlled to be turned on/off according to the applied voltage. The gate electrode 121 may be connected to, for example, a word line, and a voltage for turning on or off the memory cell MC may be applied to the gate electrode 121 through the word line.

The interlayer insulating layer 115 may serve as a spacer layer for insulation between the gate electrodes 121. The interlayer insulating layer 115 may include, for example, silicon oxide, silicon nitride, or the like, but is not limited thereto.

A channel hole is formed to penetrate in a direction perpendicular to the substrate 101 (in the z-axis direction) in the interlayer insulation layers 115 and the gate electrodes 121. The channel hole may be formed to have, for example, a circular cross section.

The gate insulating layer 122, the second dielectric constant change layer 123, the diffusion barrier layer 124, the first dielectric constant change layer 125, and the channel layer 126 are sequentially provided on the inner wall of the channel hole. Here, each of the gate insulating layer 122, the first dielectric constant change layer 125, the second dielectric constant change layer 123, and the channel layer 126 may be formed to have a cylindrical shape extending in a direction perpendicular to the substrate 101 (in the z-axis direction). The filling insulating layer 127 may be provided inside the channel layer 126 to fill the channel hole. The filling insulating layer 127 may include, for example, silicon oxide or air, but is not limited thereto.

The gate insulating layers 122 may be provided on an inner wall of the channel hole to be in contact with the interlayer insulating layers 115 and the plurality of gate electrodes 121, respectively. The gate insulating layer 122 may be provided between each of the plurality of gate electrodes 121 and the second dielectric constant change layer 123. The gate insulating layer 122 may include various types of insulating materials. The gate insulating layer 122 may include, for example, silicon oxide, silicon nitride, or metal oxide, but is not limited thereto.

The first dielectric constant change layer 125 may be provided on the channel layer 126, and the second dielectric constant change layer 123 may be provided spaced apart from the first dielectric constant change layer 125.

The first dielectric constant change layer 125 and the second dielectric constant change layer 123 may include oxygen vacancies 130. The density of the oxygen vacancies 130 of each of the first dielectric constant change layer 125 and the second dielectric constant change layer 123 may vary according to an applied voltage.

When a predetermined voltage is applied to the gate electrode 121 corresponding to each memory cell MC, the oxygen vacancies 130 of the first dielectric constant change layer 125 may move to the second dielectric constant change layer 123, or the oxygen vacancies 130 of the second dielectric constant change layer 123 may move to the first dielectric constant change layer 125. In the first dielectric constant change layer 125 and the second dielectric constant change layer 123, the dielectric constant may be changed according to the density change of the oxygen vacancies 130 as the oxygen vacancies 130 move. For example, when the oxygen vacancies 130 move from the second dielectric constant change layer 123 to the first dielectric constant change layer 125, the dielectric constant of the second dielectric constant change layer 123 may increase and the dielectric constant of the first dielectric constant change layer 125 may decrease.

As the dielectric constant of each of the first dielectric constant change layer 125 and the second dielectric constant change layer 123 changes, the threshold voltage of the memory device 100 changes, and thus, information may be stored in the memory device 100.

The first dielectric constant change layer 125 may include, for example, hafnium oxide (HfOₓ), tantalum oxide (TaOₓ), tungsten oxide (WOₓ), gandolunium (GdOₓ), indium oxide (InOₓ), molybdenum (MoOₓ), titanium oxide (TiOₓ), vanadium oxide (VOₓ), zinc oxide (ZnO), nickel oxide (NiO), aluminum oxide (AIOₓ), or indium gallium zinc oxide (InGaZnOₓ). The thickness of the first dielectric constant change layer 125 may range from, for example, 1 nm to 20 nm. The thickness of the first dielectric constant change layer 125 may range from, for example, 1 nm to 10 nm.

The second dielectric constant change layer 125 may include, for example, HfOₓ, TaOₓ, WOₓ, GdOₓ, InOₓ, MoOₓ, TiOₓ, VOₓ, ZnO, NiO, AlOₓ, or InGaZnOₓ. The thickness of the second dielectric constant change layer 123 may range from, for example, 1 nm to 20 nm. The thickness of the second dielectric constant change layer 123 may range from, for example, 1 nm to 10 nm.

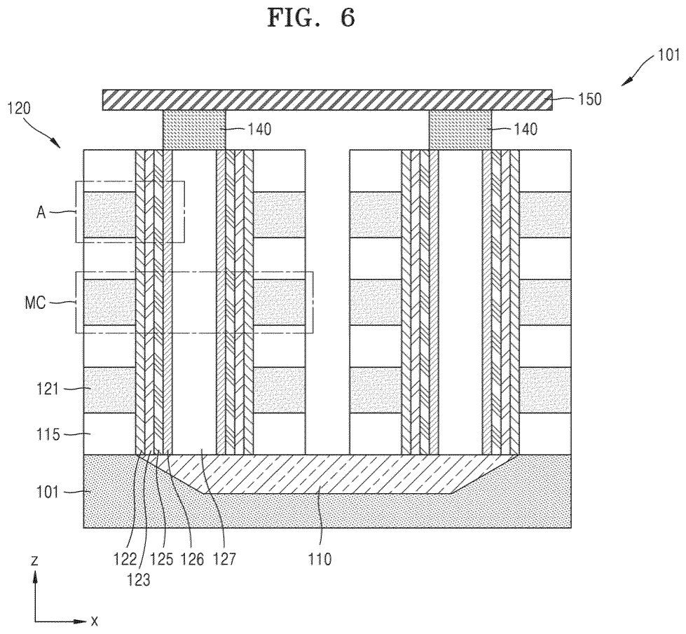

The diffusion barrier layer 124 may include a material selectively diffusing only oxygen ions. The diffusion barrier layer 124 may selectively diffuse the oxygen ions and then prevent the oxygen ions from being diffused again. The diffusion barrier layer 124 may include, for example, aluminum oxide (Al₂O₃), HfO₂, samarium nickel oxide (SmNiOₓ), WO₃, yttrium stabilized zirconium oxide (YSZ), or VO₂, but is not limited thereto. Although FIG. 1 shows that the diffusion barrier layer 124 is provided between the first dielectric constant change layer 125 and the second dielectric constant change layer 123, the diffusion barrier layer 124 may be omitted, and the first dielectric constant change layer 125 and the second dielectric constant change layer 123 may come into contact with each other, as illustrated in FIG. 6.

The channel layer 126 may include a semiconductor material. The channel layer 126 may include, for example, silicon (Si), germanium (Ge), silicon germanium (SiGe), group III-V semiconductor, or the like. In addition, the channel layer 126 may include, for example, oxide semiconductors, nitride semiconductors, oxynitride semiconductors, two-dimensional (2D) semiconductor materials, quantum dots, or organic semiconductors. Here, the oxide semiconductor may include, for example, indium tin oxide (ITO), fluoride doped tin oxide (FTO), or InGaZnO, the two-dimensional semiconductor material may include, for example, transition metal dichalcogenide (TMD) or graphene, and the quantum dot (QD) may include a colloidal QD, a nanocrystal structure, or the like. However, it is only an example, and the embodiments are not limited thereto.

The channel layer 126 may further include a dopant. Here, the dopant may include a p-type dopant or an n-type dopant. The p-type dopant may include, for example, a Group III element such as boron (B), Al, Ga, In, or the like, and the n-type dopant may include, for example, a Group V element such as phosphorous (P), arsenic (As), antimony (Sb), or the like.

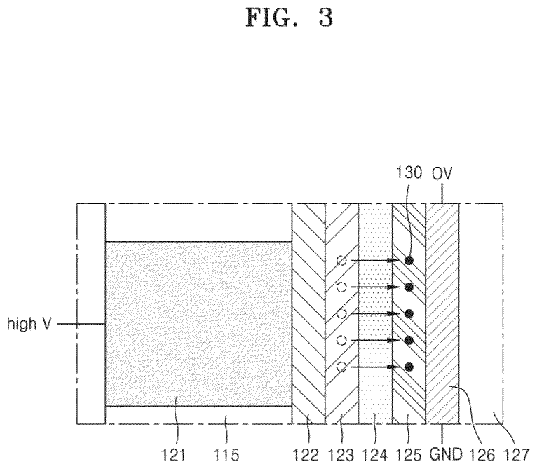

FIGS. 3 to 5 are diagrams illustrating operation methods of memory cells.

FIG. 3 illustrates a write operation of a memory cell.

Referring to FIG. 3, a relatively high voltage is applied to the gate electrode 121 of the memory cell, one end of the channel layer 126 is grounded GND, and a zero voltage 0 V is applied to the other end of the channel layer 126. In this case, the oxygen vacancies 130 of the second dielectric constant change layer 123 moves to the first dielectric constant change layer 125. Since the negatively charged oxygen ions move in a direction closer to the gate electrode 121 to which the positive voltage is applied, the oxygen vacancies 130 moves in a direction farther away from the gate electrode 121 in the opposite direction thereto. As the oxygen vacancies 130 move, the dielectric constant of the second dielectric constant change layer 123 and the dielectric constant of the first dielectric constant change layer 125 change. As the dielectric constant changes, the threshold voltage of the memory device changes. Desired information of 1 or 0 may be written to a selected memory cell according to a change in a threshold voltage of the memory device.

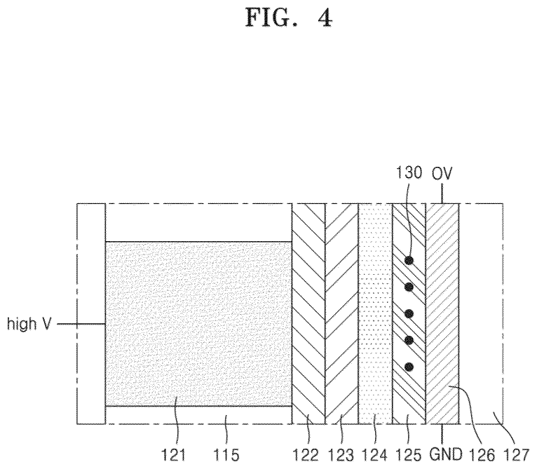

FIG. 4 illustrates a read operation of a memory device.

Referring to FIG. 4, a relatively high voltage is applied to the gate electrode 121 of the memory device, one end of the channel layer 126 is grounded GND, and a zero voltage 0 V is applied to the other end of the channel layer 126. Since the threshold voltage of the memory device changes as the dielectric constant changes in the write operation, the state 1 or 0 of the memory cell may be confirmed by measuring the current flowing through the memory cell when the same voltage is applied.

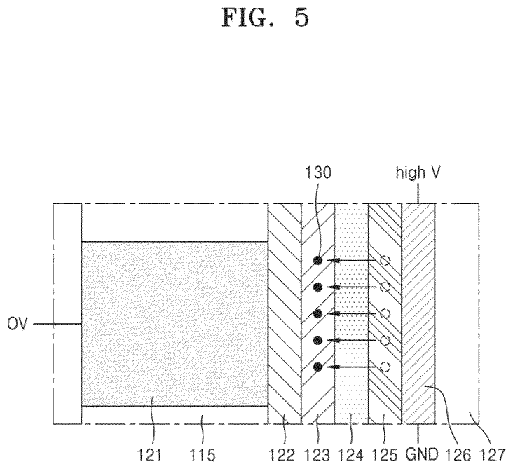

FIG. 5 illustrates an erasure operation of a memory device.

Referring to FIG. 5, a zero voltage 0 V is applied to the gate electrode 121 of the memory device, one end of the channel layer 126 is grounded GND, and a relatively high voltage is applied to the other end of the channel layer 126. In this case, the oxygen vacancies 130 of the first dielectric constant change layer 125 moves to the second dielectric constant change layer 123. As the oxygen vacancies 130 move, the dielectric constant of the second dielectric constant change layer 123 and the dielectric constant of the first dielectric constant change layer 125 change. As the dielectric constant changes, the threshold voltage of the memory device changes. The threshold voltage of the memory device may return to a before-the-write-operation state.

FIG. 6 is a cross-sectional view illustrating a structure of a memory device according to an example embodiment.

Referring to FIG. 6, a memory device 101 may include a substrate 101 and a plurality of memory cell arrays 120 provided on the substrate 101.

Each of the memory cell arrays 120 includes a plurality of memory cells MC arranged in one direction. Each of the memory cells MC includes channel layers 126 extending in a first direction (z-axis direction), a plurality of gate electrodes 121 spaced apart from each other in a second direction (x-axis direction) different from the first direction and alternately arranged in the first direction, gate insulating layers 122 provided corresponding to the gate electrodes 121, respectively, a first dielectric constant change layer 125 provided in each of the channel layers 126, a second dielectric constant change layer 123 arranged to be spaced apart from the first dielectric constant change layer 125 in the second direction, and a filling insulating layer 127. Each of the gate insulating layers 122, the first dielectric constant change layers 125, the second dielectric constant change layers 123, and the channel layers 126 is provided to extend in a direction perpendicular to the substrate 101. and may be shared by the plurality of memory cells MC.

The memory device 101 of FIG. 6 may be the same as the memory device 100 of FIG. 1, except that the diffusion barrier layer 124 is omitted and the first dielectric constant change layer 125 and the second dielectric constant change layer 123 are provided to contact each other. In describing FIG. 6, redundant descriptions of FIG. 1 are omitted.

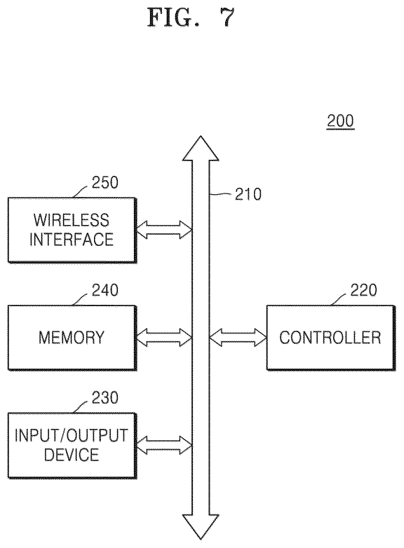

FIG. 7 is a block diagram illustrating an electronic apparatus including a memory device according to an example embodiment.

Referring to FIG. 7, the electronic apparatus 200 may be one of a PDA, a laptop computer, a portable computer, a web tablet, a wireless phone, a mobile phone, a digital music player, a wired/wireless electronic device, or a composite electronic device including at least two of them. The electronic apparatus 200 may include a controller 220, an input/output device 230, such as a keypad, a keyboard, and a display, a memory 240, and a wireless interface 250 coupled to each other through a bus 210.

The controller 220 may include, for example, one or more microprocessors, digital signal processors, microcontrollers, or the like. The memory 240 may be used, for example, to store instructions executed by the controller 220.

The memory 240 may be used to store user data. The memory 240 may include the memory device 100 of FIG. 1 or the memory device 101 of FIG. 6.

The electronic apparatus 200 may use the wireless interface 250 to transmit data to a wireless communication network communicating with a radio frequency (RF) signal or to receive data from the network. For example, the wireless interface 250 may include an antenna, a wireless transceiver, and the like. The electronic apparatus 200 may be used in a communication interface protocol of a third generation communication system, such as CDMA, GSM, NADC, E-TDMA, WCDAM, CDMA2000, etc.

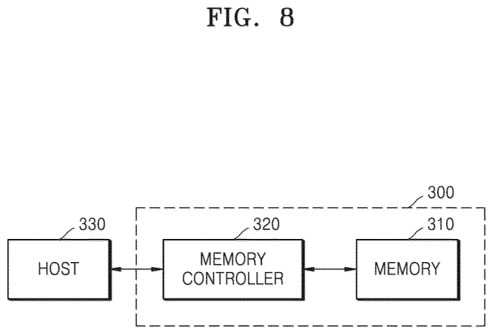

FIG. 8 is a block diagram illustrating a memory system including a memory device according to an example embodiment.

Referring to FIG. 8, a memory system 300 may include a memory 310 and a memory controller 320 for storing a relatively large amount of data. The memory controller 320 controls the memory 310 to read or write data stored in or from the memory 310 in response to a read/write request from a host 330. The memory controller 320 may configure an address mapping table for mapping an address provided from the host 330, for example, a mobile device or a computer system, to a physical address of the memory 310. The memory 310 may include the memory device 100 of FIG. 1 or the memory device 101 of FIG. 6.

The memory device according to the example embodiment described may be implemented in the form of a chip and used as a neuromorphic computing platform.

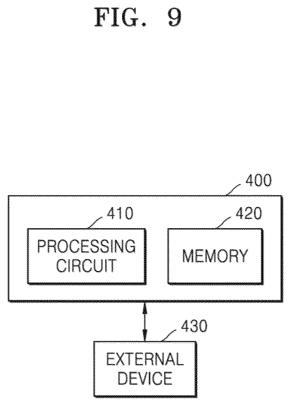

FIG. 9 is a diagram illustrating a neuromorphic device including a memory device according to an example embodiment.

Referring to FIG. 9, a neuromorphic apparatus 400 may include a processing circuitry 410 and/or a memory 420. The memory 420 of the neuromorphic device 400 may include the memory system 300 according to the example embodiment of FIG. 8.

The processing circuit 410 may be configured to control functions for driving the neuromorphic device 400. For example, the processing circuit 410 may control the neuromorphic device 400 by executing a program stored in the memory 420 of the neuromorphic device 400.

The processing circuit 410 may include hardware such as a logic circuit, a combination of hardware and software such as a processor executing the software, or a combination thereof. For example, the processor may include a central processing unit (CPU), a graphics processing unit (GPU), an application processor (AP) in the neuromorphic device 400, an arithmetic logic unit (ALU), a digital processor, a microcomputer, a field programmable gate array (FPGA), a system-on-chip (SoC), a programmable logic unit (programmable logic unit), a microprocessor, an application-specific integrated circuit (ASIC), and the like.

In addition, the processing circuit 410 may read and write various data in and from an external device 430 and execute the neuromorphic device 400 using the data. The external device 430 may include a sensor array having an external memory and/or an image sensor (e.g., a CMOS image sensor circuit).

The neuromorphic device 400 illustrated in FIG. 9 may be applied to a machine learning system. The machine learning system may utilize, for example, various artificial neural network organizations and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Such machine learning systems may include other forms of machine learning models, such as, for example, linear regression and/or logistic regression, statistical clustering, Bayesian classification, decision trees, dimensionality reduction such as principal component analysis, and expert systems; and/or combinations thereof, including ensembles such as random forests. Such machine learning models may be used to provide various services, such as image classification services, user authentication services based on biometric information or biometric data, advanced driver assistance systems (ADAS), voice assistant services, and automatic speech recognition (ASR) services, and may be installed and executed in other electronic apparatuses.

According to the memory device and the electronic apparatus according to example embodiments, data may be stored by changing the oxygen vacancies of the first dielectric constant change layer and the second dielectric constant change layer. The memory device and the electronic apparatus including the memory device have been described with reference to the example embodiments shown in the drawings. According to the example embodiments, the memory device may store data by changing the density of the oxygen vacancies of each of the first and second dielectric constant change layers.

According to the example embodiments, the memory device may overcome the deterioration characteristics of the charge as a control factor changes from the charge to the oxygen vacancy.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A memory device comprising:
a channel layer;
a first dielectric constant change layer on the channel layer;
a second dielectric constant change layer spaced apart from the first dielectric constant change layer; and
a diffusion barrier layer between the first dielectric constant change layer and the second dielectric constant change layer,
wherein the first dielectric constant change layer and the second dielectric constant change layer comprise oxygen vacancies.

2. The memory device of claim 1, wherein the first dielectric constant change layer comprises at least one of HfOₓ, TaOₓ, WOₓ, GdOₓ, InOₓ, MoOₓ, TiOₓ, VOₓ, ZnO, AlOₓ, and InGaZnOₓ.

3. The memory device of claim 1, wherein the second dielectric constant change layer comprises at least one of HfOₓ, TaOₓ, WOₓ, GdOₓ, InOₓ, MoOₓ, TiOₓ, VOₓ, ZnO, AlOₓ, and InGaZnOₓ.

4. The memory device of claim 1, wherein the diffusion barrier layer is configured to selectively diffuse oxygen ions.

5. The memory device of claim 1, wherein the diffusion barrier layer comprises at least one of Al₂O₃, HfO₂, SmNiOₓ, WO₃, yttrium stabilized zirconium oxide (YSZ) and VO2.

6. The memory device of claim 1, wherein the channel layer comprises silicon or oxide semiconductor.

7. The memory device of claim 6, wherein the oxide semiconductor comprises at least one of ITO, FTO, and InGaZnOₓ.

8. The memory device of claim 1, wherein a thickness of the first dielectric constant change layer ranges from 1 nm to 10 nm.

9. The memory device of claim 1, wherein a thickness of the second dielectric constant change layer ranges from 1 nm to 10 nm.

10. A memory device comprising
a plurality of memory cell arrays extending in a first direction normal to a first surface of a substrate,
wherein each memory cell array of the plurality of memory cell arrays comprises:
a channel layer extending in the first direction;
a plurality of gate electrodes spaced apart from each other in a second direction different from the first direction, and alternately disposed in the first direction;
a first dielectric constant change layer in the channel layer;
a second dielectric constant change layer spaced apart from the first dielectric constant change layer in the second direction; and
a diffusion barrier layer between the first dielectric constant change layer and the second dielectric constant change layer,
wherein the first dielectric constant change layer and the second dielectric constant change layer comprise oxygen vacancies.

11. The memory device of claim 10, wherein the first dielectric constant change layer comprises at least one of HfOₓ, TaOₓ, WOₓ, GdOₓ, InOₓ, MoOₓ, TiOₓ, VOₓ, ZnO, and InGaZnOₓ.

12. The memory device of claim 10, wherein the second dielectric constant change layer comprises at least one of HfOₓ, TaOₓ, WOₓ, GdOₓ, InOₓ, MoOₓ, TiOₓ, VOₓ, ZnO, and InGaZnOₓ.

13. The memory device of claim 10, wherein the diffusion barrier layer is configured to selectively diffuse oxygen ions.

14. The memory device of claim 10, wherein the diffusion barrier layer comprises at least one of Al₂O₃, HfO₂, SmNiOₓ, WO₃, and VO₂.

15. The memory device of claim 10, wherein the channel layer comprises silicon or oxide semiconductor.

16. The memory device of claim 15, wherein the oxide semiconductor comprises at least one of ITO, FTO, and InGaZnOₓ.

17. The memory device of claim 10, further comprising:
a channel hole extending in the first direction and inside the channel layer.

18. The memory device of claim 17, wherein the channel layer, the first dielectric constant change layer, the second dielectric constant change layer, and the diffusion barrier layer have a cylindrical shape in the channel hole.

19. The memory device of claim 10, further comprising:
a gate insulating layer between the plurality of gate electrodes and the second dielectric constant change layer.

20. An electronic apparatus comprising:
a memory device comprising:
a channel layer;
a first dielectric constant change layer on the channel layer;
a second dielectric constant change layer spaced apart from the first dielectric constant change layer; and
a diffusion barrier layer between the first dielectric constant change layer and the second dielectric constant change layer,
wherein the first dielectric constant change layer and the second dielectric constant change layer comprise oxygen vacancies.
